(19) United States
(12) Patent Application Publication
(10) Pub. No.: US 2023/0139507 A1
(43) Pub. Date: May 4, 2023

(54) CHARGED PARTICLE BEAM DEVICE

(71) Applicant: Hitachi High-Tech Corporation, Tokyo (JP)

(72) Inventors: Shiano ONO, Tokyo (JP); Yuuji KASAI, Tokyo (JP); Shuichi NAKAGAWA, Tokyo (JP); Toshihiko SHIMIZU, Tokyo (JP)

(21) Appl. No.: 17/918,144

(22) PCT Filed: May 19, 2020
(86) PCT No.: PCT/JP2020/019776

§ 371 Date: Oct. 11, 2022

(51) Int. Cl. H01J 37/20; H01J 37/16

(52) U.S. Cl. CPC H01J 37/20; H01J 37/16; H01J 2237/0216

(57) ABSTRACT

The present invention provides a charged particle beam device (1) capable of attenuating intrinsic vibrations of an ion pump (104) which is connected to a lens barrel (101), regardless of the length of the lens barrel (101). A charged particle beam device (1) according to the present invention comprises: a lens barrel (101) for irradiating a sample (108) with a charged particle beam (106); an ion pump (104) which is connected to the lens barrel (101) and which evacuates the air inside the lens barrel (101); and a support member (117), one end of which is connected to the ion pump (104), and the other end of which is connected the lens barrel (101). The support member (117) includes a viscoelastic body (118) which is provided substantially parallel to the central axis (114) of the lens barrel (101).

### TECHNICAL FIELD

The present invention relates to a charged particle beam device, and more particularly to a charged particle beam device including an ion pump.

### BACKGROUND ART

A charged particle beam device such as a scanning electron microscope, a transmission electron microscope, or a semiconductor inspection device is a device that irradiates a charged particle beam generated by a charged particle beam source arranged in an upper portion of a lens barrel onto a sample arranged inside a sample chamber, detects charged particles obtained by this irradiation, and visualizes information on the shape and the composition of the sample. The charged particle beam device can obtain information on the shape and the composition of a sample with high resolution in a range of micrometer, nanometer, or sub-nanometer. Accordingly, the charged particle beam device is currently widely used, for example, in a manufacturing site of semiconductor devices and the like.

In the lens barrel of the charged particle beam device, an electron lens is disposed for irradiating a charged particle beam onto a sample or forming an image on the sample, and the like. In recent years, in order to satisfy the request for the high resolution or the high throughput, attempts have been made with respect to a charged particle beam device such that the electronic lenses are formed in multiple stages or adopts the complicated configuration. As a result, a length of the lens barrel has been elongated and has become large-sized.

In a charged particle beam device, an ion pump is connected to an area in the vicinity of a charged particle beam source, that is, to an upper portion of a lens barrel. The ion pump maintains the inside of the lens barrel in an ultra-high vacuum thus preventing the contamination of the charged particle beam source. In many cases, the ion pump is connected to the upper portion of the lens barrel in a cantilever manner. That is, the ion pump is supported by the lens barrel in a state where only one end of the ion pump is connected to the lens barrel. Therefore, when a reaction force generated when a stage that moves a sample is driven acts on a sample chamber, the natural vibration of the ion pump is excited by way of the lens barrel.

The ion pump is formed of components including a magnet. Therefore, in the charged particle beam device, a charged particle beam is shaken by the fluctuation of a magnetic field accompanying the natural vibration of the ion pump. As a result, the quality of an observation image is deteriorated. During a period in which the quality of an observation image is deteriorated to an extent that the observation is affected, it is necessary to interrupt the observation. As a result, the throughput is decreased. To increase the throughput, it is necessary to quickly attenuate the natural vibration of the ion pump immediately after the stage is driven.

Patent Literature 1 describes an example of a charged particle beam device capable of attenuating the natural vibration of an ion pump. In the charged particle beam device described in Patent Literature 1, a vibration absorber that includes a viscoelastic sheet is disposed between a frame fixed to a sample chamber and an ion pump connected to a lens barrel. With such a configuration, the natural vibration of the ion pump is attenuated within a short time.

Patent Literature 2 describes a charged particle beam device that includes a damping member. One end of the damping member is fixed to a sample chamber, and the other end of the damping member is fixed to a lens barrel. The damping member includes a viscoelastic sheet. With such a configuration, it is possible to suppresses the inclination of the lens barrel, and the vibration of the lens barrel in a vertical direction.

Patent Literature 3 describes a charged particle beam device that includes a plurality of lens barrels. The charged particle beam device also includes a connection member having one end that is attached to one lens barrel and the other end that is attached to another lens barrel. The connection member includes a viscoelastic sheet. With such a configuration, it is possible to suppress the vibration of the plurality of lens barrels.

### CITATION LIST

### Patent Literatures

PTL 1: Japanese Patent Application Laid-Open No. 2011-003414

PTL 2: WO 2011/043391 A

PTL 3: Japanese Patent Application Laid-Open No. 2017-152276

### SUMMARY OF INVENTION

### Technical Problem

In the invention described in Patent Literature 1, in the charged particle beam device, in order to attenuate the natural vibration of the ion pump, the ion pump is supported from the sample chamber using the vibration absorber and the frame. In the charged particle beam device, as described above, due to the formation of the electronic lens in multiple stages and the adoption of the complicate configuration, a length of the lens barrel has been elongated and large-sized. When the lens barrel is elongated, a distance between the ion pump and the sample chamber is increased. Accordingly, in a case where the ion pump is supported from the sample chamber as disclosed in Patent Literature 1, a frame that forms a support body becomes large-sized. When a support body becomes large-sized, the weight of the entire charged particle beam device is increased, and the manufacturing cost is increased. Accordingly, the large-sizing of the support body is not desirable.

As disclosed in Patent Literature 2 and Patent Literature 3, in a case where the lens barrel is supported by the member that includes a viscoelastic body, the vibration of the lens barrel can be attenuated. However, the natural vibration of the ion pump that is connected to the lens barrel cannot be attenuated.

It is an object of the present invention to provide a charged particle beam device that can attenuate the natural vibration of the ion pump that is connected to the lens barrel regardless of a length of a lens barrel.

### SOLUTION TO PROBLEM

A charged particle beam device according to the present invention includes: a lens barrel that irradiates a charged particle beam to a sample; an ion pump that is connected to the lens barrel, and evacuates an inside of the lens barrel; and a support member having one end connected to the ion pump and the other end connected to the lens barrel. The support member includes a viscoelastic body that is disposed substantially parallel to a central axis of the lens barrel.

### Advantageous Effects of Invention

The present invention provides a charged particle beam device capable of attenuating natural vibration of an ion pump which is connected to a lens barrel regardless of a length of the lens barrel.

### BRIEF DESCRIPTION OF DRAWINGS

FIG. 1 is a schematic view illustrating an overall configuration of a conventional charged particle beam device.

FIG. 2A is a view for explaining directions of modes of natural vibration of an ion pump.

FIG. 2B is a top plan view of a lens barrel, a flange, a pipe, and the ion pump illustrated in FIG. 2A.

FIG. 2C is a right side view of the lens barrel, the flange, the pipe, and the ion pump illustrated in FIG. 2A.

FIG. 2D is a front view of the lens barrel, the flange, the pipe, and the ion pump illustrated in FIG. 2A.

FIG. 3 is a schematic view illustrating an overall configuration of a charged particle beam device according to an embodiment 1 of the present invention.

FIG. 4 is a view illustrating an example of a configuration of a laminated structural body.

FIG. 5A is an exploded view of a support member that includes the laminated structural body.

FIG. 5B is a view illustrating the lens barrel to which the support member that includes the laminated structural body is connected and the ion pump.

FIG. 6 is a schematic view illustrating an overall configuration of a charged particle beam device according an embodiment 2 of the present invention.

FIG. 7 is a schematic view illustrating the configuration of the charged particle beam device according to the embodiment 2 of the present invention in which a support member includes one viscoelastic body.

FIG. 8A is a perspective view illustrating a configuration in which a first lens barrel side support body is connected to a plurality of portions of a lens barrel of the charged particle beam device according to the embodiment 2 of the present invention.

FIG. 8B is a cross-sectional view illustrating a configuration in which the first lens barrel side support body is connected to the plurality of portions of the lens barrel of the charged particle beam device according to the embodiment 2 of the present invention.

FIG. 9 is a schematic view illustrating a support member and a lens barrel of a charged particle beam device according to an embodiment 3 of the present invention.

FIG. 10A is a view for explaining natural vibration of an ion pump in a configuration of a charged particle beam device in which two ion pumps are connected to a lens barrel side by side in a z direction, and these two ion pumps are connected to each other by a connecting member.

FIG. 10B is a top plan view of a lens barrel, a flange, a pipe, a first ion pump, a second ion pump, and the connecting member illustrated in FIG. 10A.

FIG. 10C is a right side view of the lens barrel, the flange, the pipe, the first ion pump, the second ion pump, and the connecting member illustrated in FIG. 10A.

FIG. 10D is a front view of the lens barrel, the flange, the pipe, the first ion pump, the second ion pump, and the connecting member illustrated in FIG. 10A.

FIG. 11 is a perspective view illustrating a lens barrel, a first ion pump, and a second ion pump of a charged particle beam device according to an embodiment 4 of the present invention.

FIG. 12A is a view illustrating a configuration of the charged particle beam device illustrated in FIG. 11 in which a viscoelastic body 118D is not provided.

FIG. 12B is a view illustrating a configuration of the charged particle beam device illustrated in FIG. 11 in which a viscoelastic body 118A is not provided.

FIG. 13A is a perspective view illustrating a configuration of the charged particle beam device according to the embodiment 4 of the present invention in which a second support member is directly connected to the lens barrel.

FIG. 13B is a cross-sectional view illustrating a configuration of the charged particle beam device according to the embodiment 4 of the present invention in which the second support member is directly connected to the lens barrel.

### DESCRIPTION OF EMBODIMENTS

A charged particle beam device according to the present invention includes: a lens barrel that irradiates a charged particle beam to a sample; an ion pump that is connected to the lens barrel; and a support member that is connected to the ion pump. The support member includes a viscoelastic body that is connected to the ion pump and the lens barrel and is disposed substantially parallel to a central axis of the lens barrel. In the charged particle beam device according to the present invention, it is unnecessary to support the ion pump from the sample chamber. Accordingly, it is possible to attenuate the natural vibration of the ion pump within a short time regardless of a length of the lens barrel. Therefore, the charged particle beam device according to the present invention can acquire a high-resolution observation image at a high speed without increasing the size of the support member of the ion pump. Accordingly, it is possible to enhance the throughput.

First, a conventional charged particle beam device is described. In the charged particle beam device, a charged particle beam that is irradiated to a sample is an electron beam or an ion beam. Hereinafter, as an example, a charged particle beam device that irradiates an electron beam to a sample is described.

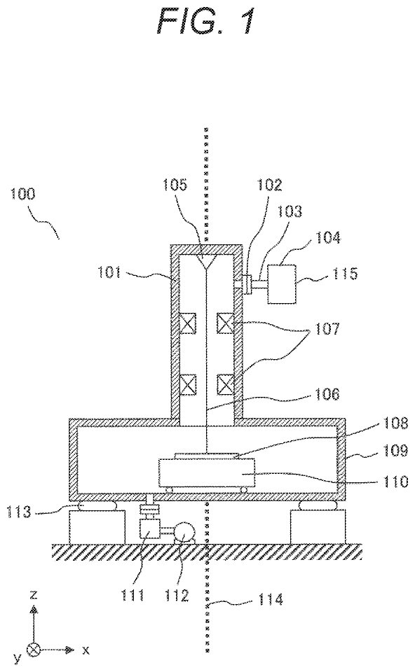

FIG. 1 is a schematic view illustrating an overall configuration of a conventional charged particle beam device 100. The conventional charged particle beam device 100 includes a lens barrel 101, an ion pump 104, a sample chamber 109, and a stage 110.

An electron gun 105 is disposed in an upper portion of the lens barrel 101, and an electron beam 106 irradiated from the electron gun 105 is focused by electron lenses 107. The central axis of the lens barrel 101 is referred to as a lens barrel central axis 114. A direction parallel to the lens barrel central axis 114 is a vertical direction.

The ion pump 104 is connected to the upper portion of the lens barrel 101 in a cantilever manner (that is, only one end of the ion pump 104 being supported by the lens barrel 101) by way of a pipe 103 and a flange 102. The ion pump 104 maintains the upper portion of the lens barrel 101 in an ultrahigh vacuum state.

The sample chamber 109 is evacuated to a vacuum by a turbo molecular pump 111 and a dry pump 112, and a sample 108 that is an object to be observed is disposed in the sample chamber 109. The sample chamber 109 is supported on an anti-vibration mount 113 and so that the sample chamber 109 is insulated from floor vibration.

The stage 110 is disposed in the sample chamber 109. The stage 110 is driven so as to move the sample 108. The sample 108 is placed on the stage 110 at the time of observation.

The electron beam 106 is focused as an electron spot on the sample 108 by the electron lenses 107. During a period in which the sample 108 is observed, the electron spot moves on the sample 108 as a probe by operating a scanning coil (not illustrated). A signal (electron) generated at this time of the operation is converted into an electric signal by a detector (not illustrated). The signal is combined with the coordinates of the electronic spot, and the signal is visualized as information on the shape and the composition of the sample 108.

In the description made hereinafter, in FIG. 1, a direction in which the ion pump 104 is connected to the lens barrel 101 as viewed from the lens barrel 101 is defined as an x direction, a direction that is orthogonal to the x direction and is orthogonal to the lens barrel central axis 114 is defined as a y direction, and a direction (vertical direction) that is parallel to the lens barrel central axis 114 is defined as a z direction. Further, the rotation directions around the x axis, the y axis, and the z axis are represented by θx, θy, and θz, respectively. Furthermore, the ion pump 104 is treated as a hexahedron. In this case, a surface of the ion pump 104 that is disposed on a side opposite to a surface of the ion pump 104 and faces the flange 102 and the lens barrel 101 to which the pipe 103 is connected is referred to as a mounting surface 115. The mounting surface 115 of the ion pump 104 is disposed parallel to the yz plane.

The xy plane is a plane perpendicular to the z direction, that is, a plane perpendicular to the lens barrel central axis 114 (vertical direction). The yz plane is a plane perpendicular to the x direction, that is, a plane perpendicular to the direction in which the ion pump 104 is connected as viewed from the lens barrel 101. The zx plane is a plane perpendicular to the y direction, that is, a plane parallel to the x direction and the z direction.

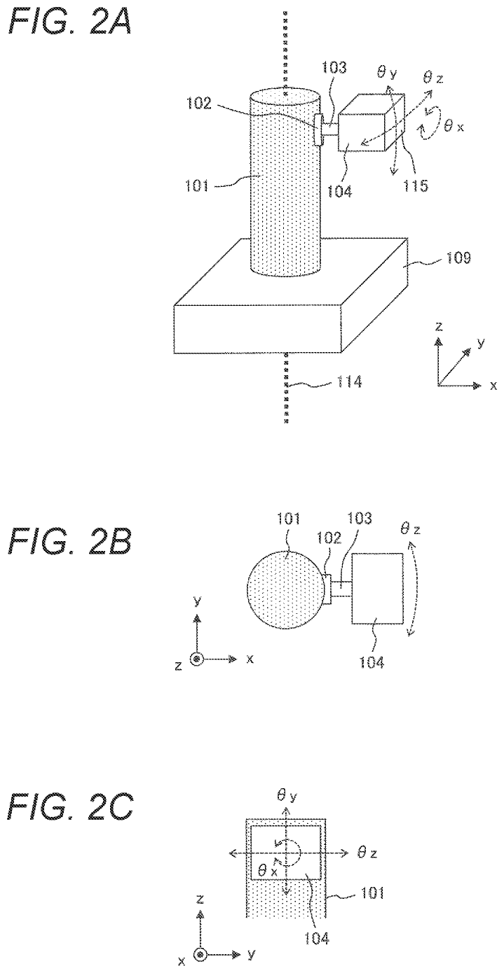

FIG. 2A is a view for explaining directions of modes of natural vibration of the ion pump 104. Experiments and an analysis have revealed that in a case where a reaction force that is generated when the stage 110 is driven acts on the sample chamber 109, the reaction force is transmitted to the ion pump 104 through the lens barrel 101, the flange 102, and the pipe 103 so that the natural vibration of the ion pump 104 is excited in the θx, θy, and θz directions. The mode of the natural vibration of the ion pump 104 in the θx direction is a mode in which the ion pump 104 rotates about the x axis using the pipe 103 as the central. The mode of the natural vibration of the ion pump 104 in the θy direction is a mode in which the ion pump 104 rotates about the y axis using the connection portion between the pipe 103 and the ion pump 104 as the central. The mode of the natural vibration of the ion pump 104 in the θz direction is a mode in which the ion pump 104 rotates about the z axis using the connection portion between the pipe 103 and the ion pump 104 as the central.

FIG. 2B, FIG. 2C, and FIG. 2D are a top plan view, a right side view, and a front view, respectively, of the lens barrel 101, the flange 102, the pipe 103, and the ion pump 104 illustrated in FIG. 2A when a zx plane is set as a front surface. As illustrated in FIG. 2B, the mode in the θz direction has a component parallel to the xy plane (surface of a sheet on which drawings are drawn). As illustrated in FIG. 2C, the modes in the θx direction, the θy direction, and the θz direction each have a component parallel to the yz plane (surface of a sheet on which the drawing is drawn). As illustrated in FIG. 2D, the mode in the θy direction has a component parallel to the zx plane (surface of the sheet on which the drawing is drawn).

The ion pump 104 is formed of components including a magnet. Therefore, in the charged particle beam device, the electron beam 106 is shaken by a change in a magnetic field accompanying the vibration of the ion pump 104. As a result, the quality of an observation image is deteriorated. During a period in which the quality of an observation image is deteriorated to an extent that the observation is affected, it is necessary to interrupt the observation. As a result, the throughput is decreased. In order to enhance the throughput, it is necessary to quickly (for example, within 0.1 seconds) attenuate the natural vibration of the ion pump 104 immediately after the sample 108 is moved to the observation position by driving the stage 110.

Hereinafter, the charged particle beam devices of the embodiments of the present invention will be described with reference to the drawings. In the drawings used in the present specification, the same or corresponding components are denoted by the same symbols, and there may be a case where the repeated description of these components is omitted.

In the following embodiment, as an example, a charged particle beam device that irradiates an electron beam 106 to a sample 108 is described. The description is made by taking a semiconductor inspection device as an example of the charged particle beam device. As described previously, the charged particle beam that is irradiated to the sample 108 in the charged particle beam device is an electron beam or an ion beam. Accordingly, the charged particle beam device according to the present invention can also irradiate an ion beam to the sample 108. In addition, the contents described in the following embodiments are not limited to the configuration for attenuating the natural vibration of an ion pump 104. That is, the contents can also be applied to a configuration for attenuating the vibration of a device that is mounted on the lens barrel 101 at the time of observing the sample 108 (for example, a detector, an objective diaphragm, a side entry stage, a feedthrough, or a non-evaporable getter pump, or the like).

### Embodiment 1

Hereinafter, a charged particle beam device according to an embodiment 1 of the present invention will be described with reference to the drawings.

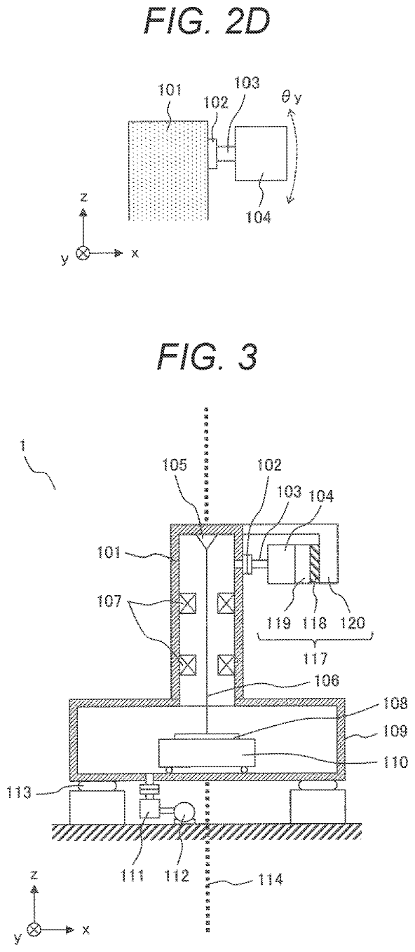

FIG. 3 is a schematic view illustrating an overall configuration of the charged particle beam device 1 according the present embodiment. The charged particle beam device 1 according to the present embodiment differs from the conventional charged particle beam device 100 illustrated in FIG. 1 with respect to a point that a support member 117 is connected to a lens barrel 101 and the ion pump 104. Hereinafter, the points that make the charged particle beam device 1 according to the present embodiment differ from the conventional charged particle beam device 100 are mainly described.

Similarly to the conventional charged particle beam device 100, the lens barrel 101 is a member for irradiating the sample 108 with the charged particle beam (electron beam 106). A lens barrel central axis 114 that is a central axis of the lens barrel 101 is parallel to a vertical direction (z direction).

One end of the ion pump 104 is connected to an upper portion of the lens barrel 101 by way of a pipe 103 and a flange 102. The ion pump 104 evacuates the inside of the lens barrel 101 to maintain the inside of the lens barrel 101 in an ultrahigh vacuum state.

The support member 117 includes an ion pump-side support body 119, a lens barrel side support body 120, and a viscoelastic body 118. One end the support member 117 is connected to the ion pump 104, and the other end of the support member 117 is connected to the lens barrel 101. The support member 117 is provided as a member that attenuates the vibration of the ion pump 104. The ion pump-side support body 119 is connected to the ion pump 104. The lens barrel side support body 120 is connected to the lens barrel 101. The viscoelastic body 118 is disposed substantially parallel to a lens barrel central axis 114, and is disposed between the ion pump-side support body 119 and the lens barrel side support body 120. In FIG. 3, the viscoelastic body 118 is disposed substantially parallel to a yz plane.

One end of the ion pump 104 is connected to the lens barrel 101, and the other end of the ion pump 104 is connected to the support member 117. Since the support member 117 is connected to the lens barrel 101, the other end of the ion pump 104 is connected to the lens barrel 101 by way of the support member 117.

In the charged particle beam device 1 according to the present embodiment, one end of the ion pump 104 is connected to the lens barrel 101, and the other end of the ion pump 104 is connected to the lens barrel 101 by way of the support member 117 that includes the viscoelastic body 118. Accordingly, it is possible to attenuate the natural vibration of the ion pump 104 connected to the lens barrel 101 regardless of a length of the lens barrel 101.

As has been described with reference to FIG. 2C, the natural vibration of the ion pump 104 that is excited in the θx direction, in the θy direction, and in the θz direction has a component parallel to the yz plane. In the present embodiment, as illustrated in FIG. 3, the viscoelastic body 118 is arranged substantially parallel to the yz plane. Accordingly, the viscoelastic body 118 can attenuate the natural vibration of the ion pump 104 excited in any directions consisting of the θx direction, the θy direction, and the θz direction.

In order to sufficiently attenuate the natural vibration of the ion pump 104, it is preferable that the viscoelastic body 118 be formed using a material (for example, a polymer material such as rubber) having a larger attenuation ratio than materials used for forming the lens barrel 101, the ion pump 104, the ion pump-side support body 119, and the lens barrel side support body 120.

The shape of the viscoelastic body 118 is arbitrary, and can be, for example, a sheet shape or a coin shape. To increase the attenuation of the vibration of the ion pump 104, a thickness of the viscoelastic body 118 may be reduced or an area of the viscoelastic body 118 may be increased.

The viscoelastic body 118 is not necessarily disposed in parallel to the lens barrel central axis 114. For example, provided that an angle between a seat surface of the viscoelastic body 118 (the seat surface that is brought into contact with the ion pump-side support body 119 or the seat surface that is brought into contact with the lens barrel side support body 120) and the lens barrel central axis 114 (that is, an angle of the viscoelastic body 118 with respect to the z direction) is 30 degrees or less, the natural vibration of the ion pump 104 can be sufficiently attenuated.

The sheet surface of the viscoelastic body 118 is not necessarily parallel to the yz plane. For example, provided that the angle between the sheet surface and the yz plane of the viscoelastic body 118 is 30 degrees or less, the natural vibration of the ion pump 104 can be sufficiently attenuated.

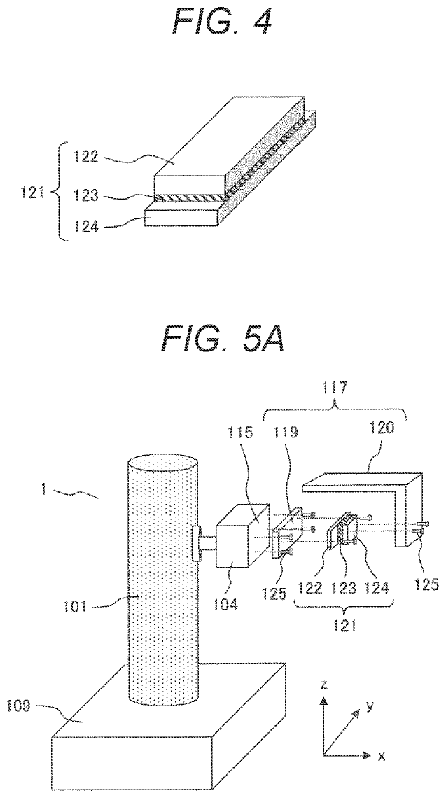

When a polymer material is used as the material of the viscoelastic body 118, the viscoelastic body 118 cannot withstand a high temperature during baking of the ion pump 104. Therefore, at the time of baking the ion pump 104, it is necessary to remove the viscoelastic body 118 from the ion pump 104. To enable easy removal of the viscoelastic body 118 from the ion pump 104, the viscoelastic body 118 can be replaced with a laminated structural body 121 illustrated in FIG. 4, for example.

FIG. 4 is a view illustrating an example of a configuration of the laminated structural body 121. The laminated structural body 121 includes a first support body 122, a viscoelastic body 123, and a second support body 124. The viscoelastic body 123 is disposed between the first support body 122 and the second support body 124. The laminated structural body 121 may adopt a structure where the first support body 122 and the second support body 124 that sandwich the viscoelastic body 123 therebetween are fixed by an adhesive, a double-sided tape, or the like.

As a material used for forming the first support body 122 and a material used for forming the second support body 124, it is preferable to use a material (for example, metal, ceramic, or the like) that has a smaller attenuation ratio than a material (for example, a polymer material such as rubber) used for forming the viscoelastic body 123. It is desirable that a thickness of the first support body 122 and a thickness of the second support body 124 be equal to or larger than a thickness of the viscoelastic body 123. Threaded holes (not illustrated) may be formed in the first support body 122 and the second support body 124 such that these bodies 122, 124 can be mounted on other parts.

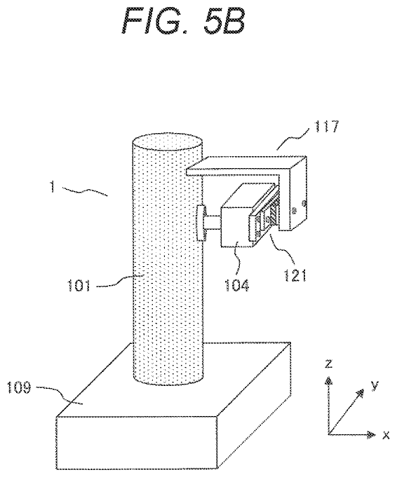

FIG. 5A is an exploded view of the support member 117 that includes the laminated structural body 121. FIG. 5B is a view illustrating the lens barrel 101 and the ion pump 104 to which the support member 117 that includes the laminated structural body 121 is connected. The support member 117 includes an ion pump-side support body 119, the laminated structural body 121, and a lens barrel side support body 120.

As illustrated in FIG. 5A, the mounting surface 115 of the ion pump 104 and the ion pump-side support body 119 of the support member 117 are connected to each other. The ion pump-side support body 119 and the first support body 122 of the laminated structural body 121 are connected to each other. The laminated structural body 121 is formed by sandwiching the viscoelastic body 123 between the first support body 122 and the second support body 124. The second support body 124 of the laminated structural body 121 and one end of the lens barrel side support body 120 of the support member 117 are connected to each other. The other end of the lens barrel side support body 120 and the lens barrel 101 are connected to each other. In a step of connecting the support member 117 to the ion pump 104 and the lens barrel 101 to each other, the connection may not be performed in the order described above.

By using fixing members 125 such as bolts or screws in performing the above-mentioned connection, the laminated structural body 121 can be easily removed from the ion pump 104 at the time of baking the ion pump 104. It must be noted that it is unnecessary to use the fixing members 125 for connecting all parts in the above-mentioned connecting operation. Some parts may be connected to each other by a method such as welding or adhesion.

With respect to the ion pump 104, some parts are assembled by welding at the time of manufacture. Accordingly, irregularities in size among ion pumps cannot be avoided. Accordingly, there may be a case where a mounting error of several millimeters may occur with respect to the position of the mounting surface 115 of the ion pump 104. In view of the above, by forming holes that are formed in the ion pump-side support body 119 and through which the fixing members 125 pass such that each hole has a diameter larger than a diameter of the fixing member 125 or is formed of an elongated hole, the position of the ion pump-side support body 119 on the mounting surface 115 can be moved. Accordingly, the position of the ion pump-side support body 119 with respect to the mounting surface 115 can be adjusted.

To suppress a change in a magnetic field fluctuation accompanying the vibration of the support member 117 itself, it is desirable that the support member 117 be partially or entirely made of a non-magnetic material. That is, the ion pump-side support body 119, the viscoelastic body 118 and the lens barrel side support body 120 that form the support member 117, the first support body 122, the viscoelastic body 123 and the second support body 124 that form the laminated structural body 121, and the fixing members 125 that are used for connection are desirably partially or entirely made of a non-magnetic material.

### Embodiment 2

Hereinafter, a charged particle beam device 1 according to an embodiment 2 of the present invention will be described with reference to the drawings.

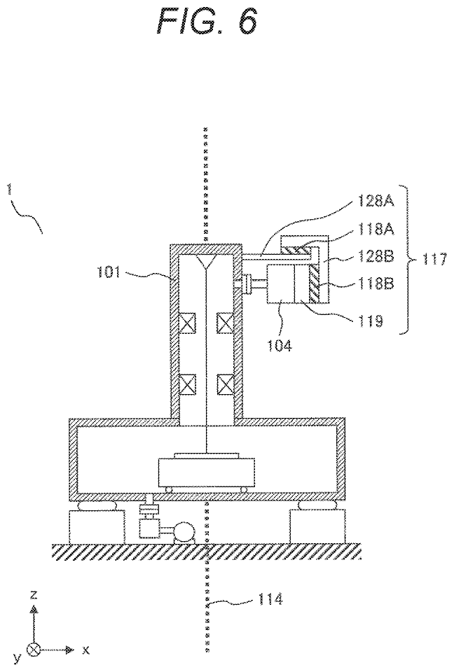

FIG. 6 is a schematic view illustrating an overall configuration of a charged particle beam device 1 according the present embodiment. The charged particle beam device 1 according to the present embodiment differs from the charged particle beam device 1 according to the embodiment 1 illustrated in FIG. 3 in the configuration of a support member 117. Hereinafter, the points that make the charged particle beam device 1 according to the present embodiment 1 differ from the conventional charged particle beam device 1 are mainly described.

The support member 117 includes an ion pump-side support body 119, a viscoelastic body 118B, a second lens barrel side support body 128B, a viscoelastic body 118A, and a first lens barrel side support body 128A. The support member 117 is a member that is connected to the ion pump 104 and the lens barrel 101, and attenuates the vibration of the ion pump 104.

The ion pump-side support body 119 is connected to the ion pump 104. The viscoelastic body 118B is disposed substantially parallel to a yz plane (that is, substantially parallel to a lens barrel central axis 114), and is disposed between an ion pump-side support body 119 and the second lens barrel side support body 128B. The second lens barrel side support body 128B connects the viscoelastic body 118B and the viscoelastic body 118A to each other. The viscoelastic body 118A is disposed substantially parallel to an xy plane (that is, substantially orthogonal to a lens barrel central axis 114), and is disposed between the second lens barrel side support body 128B and the first lens barrel side support body 128A. The first lens barrel side support body 128A is connected to the lens barrel 101.

In the charged particle beam device 1 according to the present embodiment, one end of the ion pump 104 is connected to the lens barrel 101, and the other end of the ion pump 104 is connected to the lens barrel 101 by way of the support member 117 that includes the viscoelastic bodies 118A, 118B. Accordingly, it is possible to attenuate the natural vibration of the ion pump 104 connected to the lens barrel 101 regardless of a length of the lens barrel 101.

As has been described with reference to FIG. 2B, the natural vibration of the ion pump 104 that is excited in the θz direction has a component parallel to the xy plane. In the present embodiment, as illustrated in FIG. 6, the viscoelastic body 118A is arranged substantially parallel to the xy plane. Accordingly, the viscoelastic body 118A can attenuate the natural vibration of the ion pump 104 excited in the θz direction. In the present embodiment, the viscoelastic body 118B is arranged substantially parallel to the yz plane. Accordingly, as described in the embodiment 1, the viscoelastic body 118B can attenuate the natural vibration of the ion pump 104 excited in any directions consisting of the θx direction, the θy direction, and the θz direction.

In the charged particle beam device 1 according to the present embodiment, as illustrated in FIG. 6, the support member 117 includes the viscoelastic bodies 118A and 118B. Accordingly, it is possible to attenuate all the natural vibrations of the ion pump 104 excited in the θx direction, the θy direction, and the θz direction, and particularly, it is possible to greatly attenuate the natural vibration excited in the θz direction.

The shapes of the viscoelastic bodies 118A, 118B are arbitrary, and can be, for example, a sheet shape or a coin shape.

The viscoelastic body 118A may not necessarily be disposed so as to be orthogonal to the lens barrel central axis 114, and the viscoelastic body 118B may not necessarily be disposed in parallel to the lens barrel central axis 114. For example, provided that an angle between a seat surface of the viscoelastic body 118A (the seat surface that is brought into contact with the first lens barrel side support body 128A or the seat surface that is brought into contact with the second lens barrel side support body 128B) and the lens barrel central axis 114 (that is, an angle of the viscoelastic body 118A with respect to the z direction) is 30 degrees or less, and an angle between a seat surface of the viscoelastic body 118B (the surface that is brought into contact with the ion pump-side support body 119 or the surface that is brought into contact with the second lens barrel side support body 128B) and the lens barrel central axis 114 (that is, an angle of the viscoelastic body 118B with respect to the z direction) is 30 degrees or less, the natural vibration of the ion pump 104 can be sufficiently attenuated.

Further, the sheet surface of the viscoelastic body 118A is not necessarily parallel to the xy plane, and the sheet surface of the viscoelastic body 118B is not necessarily parallel to the yz plane. For example, provided that the angle between the sheet surface of the viscoelastic body 118A and the xy plane is 30 degrees or less, and the angle between the sheet surface of the viscoelastic body 118B and the yz plane is 30 degrees or less, natural vibration of the ion pump 104 can be sufficiently attenuated.

To enable easy removal of the viscoelastic bodies 118A, 118B from the ion pump 104, the viscoelastic bodies 118A, 118B can be partially or entirely replaced with a laminated structural body 121 illustrated in FIG. 4, for example.

Further, the viscoelastic bodies 118A and 118B can also be integrally formed of one viscoelastic body.

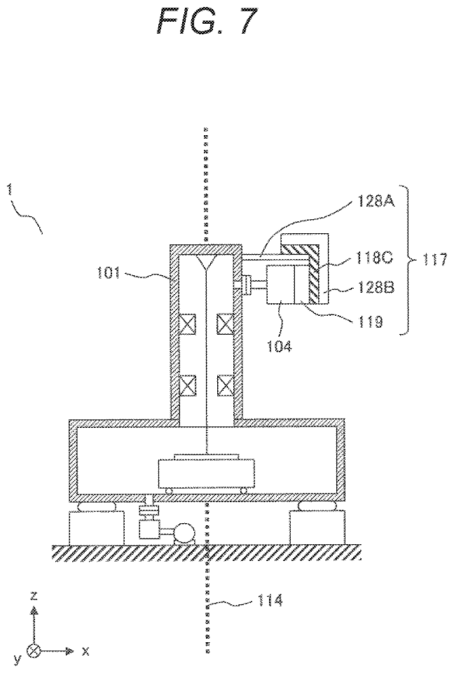

FIG. 7 is a schematic view illustrating the configuration of the charged particle beam device 1 according to the embodiment of the present invention in which a support member 117 includes one viscoelastic body 118C. The viscoelastic body 118C is provided on the support member 117 in place of the viscoelastic bodies 118A, 118B illustrated in FIG. 6. The viscoelastic body 118C includes a plane substantially parallel to the yz plane and a plane substantially parallel to the xy plane. The plane substantially parallel to the yz plane is located between the ion pump-side support body 119 and the second lens barrel side support body 128B, and serves as the viscoelastic body 118B illustrated in FIG. 6. The plane substantially parallel to the xy plane is positioned between the second lens barrel side support body 128B and the first lens barrel side support body 128A, and serves as the viscoelastic body 118A illustrated in FIG. 6.

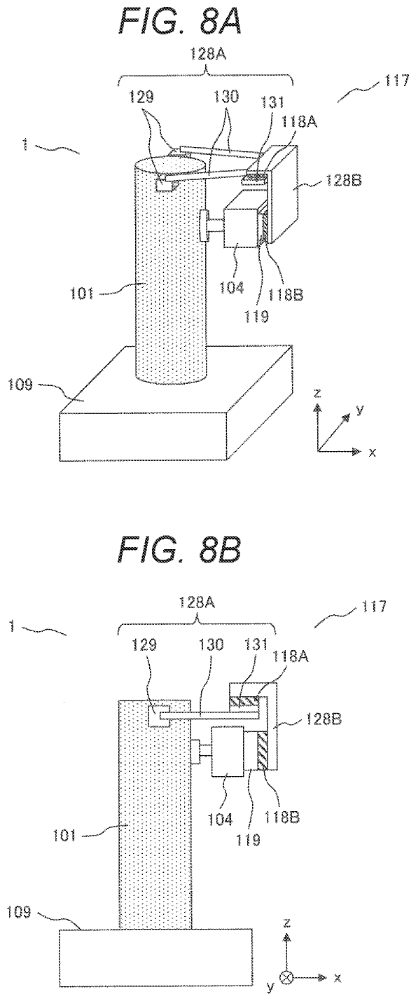

As illustrated in FIG. 8A and FIG. 8B, the first lens barrel side support body 128A of the support member 117 can also be connected to a plurality of portions of the lens barrel 101.

FIG. 8A and FIG. 8B are schematic views illustrating a configuration in which the first lens barrel side support body 128A is connected to the plurality of portions of the lens barrel 101 in the charged particle beam device 1 according to the embodiment of the present invention. FIG. 8A is a perspective view illustrating the support member 117 and the lens barrel 101. FIG. 8B is a cross-sectional view illustrating the support member 117 and the lens barrel 101. FIGS. 8A and 8B illustrate, as an example, a configuration in which the first lens barrel-side support body 128A is connected to two portions of the lens barrel 101.

The first lens barrel side support body 128A includes at least one stay support portion 131, a plurality of stays 130, and a plurality of lens barrel connecting portions 129. The stay support portion 131 is a member where the viscoelastic body 118A is sandwiched between the stay support portion 131 and the second lens barrel side support body 128B, and the stay support portion 131 supports the stay 130. The stay 130 is a holding member that connects the stay support portion 131 and the lens barrel connecting portion 129 to each other, and connects the support member 117 to a plurality of portions of the lens barrel 101. The lens barrel connecting portion 129 is provided at a plurality of portions in the circumferential direction of the lens barrel 101, and is a member to which the stay 130 is connected.

The first lens barrel side support body 128A of the support member 117 is connected to a plurality of portions of the lens barrel 101 by a plurality of stays 130.

As illustrated in FIG. 8A and FIG. 8B, the configuration is adopted where the first lens barrel side support body 128A of the support member 117 is connected to the plurality of positions of the lens barrel 101 in the circumferential direction (that is, on the xy plane) of the lens barrel 101. With such a configuration, compared with the configuration where the support member 117 is connected to the lens barrel 101 at one position as illustrated in FIG. 5B, the support rigidity of the ion pump 104 on the xy plane with respect to the lens barrel 101 is increased. Therefore, among the modes of the natural vibration of the ion pump 104, in particular, a mode excited in the θz direction (FIG. 2B) can be greatly attenuated.

### Embodiment 3

Hereinafter, a charged particle beam device 1 according to an embodiment 3 of the present invention will be described with reference to the drawings.

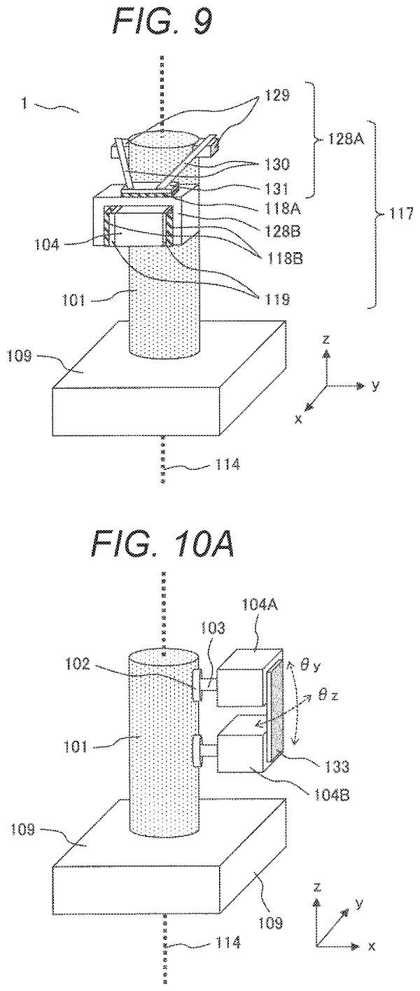

FIG. 9 is a perspective view illustrating a support member 117 and a lens barrel 101 of a charged particle beam device 1 according to an embodiment 3 of the present invention. The charged particle beam device 1 according to the present embodiment differs from the charged particle beam device 1 according to the embodiment 2 illustrated in FIG. 8A and FIG. 8B in the configuration of a support member 117. As an example of the charged particle beam device 1 according to an embodiment 3, FIG. 9 illustrates the charged particle beam device 1 where a first lens barrel side support body 128A of a support member 117 is connected to a plurality of portions of the lens barrel 101 in the same manner as the charged particle beam device 1 illustrated in FIG. 8A and FIG. 8B. Hereinafter, the points that make the charged particle beam device 1 according to the present embodiment differ from the conventional charged particle beam device 1 illustrated in FIG. 8A and FIG. 8B are mainly described.

The support member 117 includes an ion pump-side support body 119, a viscoelastic body 118B, a second lens barrel side support body 128B, a viscoelastic body 118A, and a first lens barrel side support body 128A. The support member 117 is a member that is connected to the ion pump 104 and the lens barrel 101, and attenuates the vibration of the ion pump 104.

The ion pump-side support body 119 is connected to the ion pump 104. The viscoelastic bodies 118B are disposed substantially parallel to a lens barrel central axis 114 and substantially parallel to a zx plane (that is, substantially parallel to a lens barrel central axis 114), and is disposed between an ion pump-side support body 119 and the second lens barrel side support body 128B. In FIG. 9, the viscoelastic body 118B is disposed on each of two side surfaces (zx planes) of the ion pump 104. The second lens barrel side support body 128B connects the viscoelastic body 118B and the viscoelastic body 118A to each other. In FIG. 9, the second lens barrel side support body 128B is disposed so as to cover the ion pump 104 and the viscoelastic body 118B. The viscoelastic body 118A is disposed substantially parallel to an xy plane (that is, substantially orthogonal to a lens barrel central axis 114), and is disposed between the second lens barrel side support body 128B and the first lens barrel side support body 128A. The first lens barrel side support body 128A includes a stay support portion 131, a stay 130, and a lens barrel connecting portion 129, and is connected to the lens barrel 101.

In the charged particle beam device 1 according to the present embodiment, one end of the ion pump 104 is connected to the lens barrel 101, and the other end of the ion pump 104 is connected to the lens barrel 101 by way of the support member 117 that includes the viscoelastic bodies 118A, 118B. Accordingly, it is possible to attenuate the natural vibration of the ion pump 104 connected to the lens barrel 101 regardless of a length of the lens barrel 101.

As has been described with reference to FIG. 2B, the natural vibration of the ion pump 104 that is excited in the θz direction has a component parallel to the xy plane. As has been described with reference to FIG. 2D, the modes that is excited in the θy direction has a component parallel to the zx plane. In the present embodiment, as illustrated in FIG. 9, the viscoelastic body 118A is arranged substantially parallel to the xy plane. Accordingly, the viscoelastic body 118A can attenuate the natural vibration of the ion pump 104 excited in the θz direction. The viscoelastic bodies 118B are arranged substantially parallel to the zx plane. Accordingly, the viscoelastic body 118B can attenuate the natural vibration of the ion pump 104 excited in the θy direction.

The shapes of the viscoelastic bodies 118A, 118B are arbitrary, and can be, for example, a sheet shape or a coin shape.

The viscoelastic body 118A may not necessarily be disposed so as to be orthogonal to the lens barrel central axis 114, and the viscoelastic body 118B may not necessarily be disposed in parallel to the lens barrel central axis 114. For example, provided that an angle between a seat surface of the viscoelastic body 118A (the seat surface that is brought into contact with the first lens barrel side support body 128A or the seat surface that is brought into contact with the second lens barrel side support body 128B) and the lens barrel central axis 114 (that is, an angle of the viscoelastic body 118A with respect to the z direction) is 30 degrees or less, and an angle between a seat surface of the viscoelastic body 118B (the surface that is brought into contact with the ion pump-side support body 119 or the surface that is brought into contact with the second lens barrel side support body 128B) and the lens barrel central axis 114 (that is, an angle of the viscoelastic body 118B with respect to the z direction) is 30 degrees or less, the natural vibration of the ion pump 104 can be sufficiently attenuated.

Further, the sheet surface of the viscoelastic body 118A is not necessarily parallel to the xy plane, and the sheet surfaces of the viscoelastic bodies 118B are not necessarily parallel to the zx plane. For example, provided that the angle between the sheet surface of the viscoelastic body 118A and the xy plane is 30 degrees or less and the angle between the sheet surface of the viscoelastic body 118B and the zx plane is 30 degrees or less, the natural vibration of the ion pump 104 can be sufficiently attenuated.

To enable easy removal of the viscoelastic bodies 118A, 118B from the ion pump 104, the viscoelastic bodies 118A, 118B can be partially or entirely replaced with a laminated structural body 121 illustrated in FIG. 4, for example.

In the present embodiment (FIG. 9), the viscoelastic body 118B of the support member 117 is disposed substantially parallel to the zx plane. In the embodiment 2 (for example, FIG. 8A and FIG. 8B), the viscoelastic body 118B is disposed substantially parallel to a yz plane. That is, in the present embodiment, the direction of the viscoelastic body 118B differs from that the corresponding direction in embodiment 2. In the configuration of the present embodiment, since the viscoelastic bodies 118B are disposed on the side surface (zx plane) of the ion pump 104. Accordingly, it is possible to make a space around the surface (yz plane) of the ion pump 104 opposite to the surface to which the lens barrel 101 is connected. Therefore, in the configuration of the present embodiment, for example, it is possible to easily perform an operation of arranging wiring such as a cable of a baking heater around the ion pump 104.

### Embodiment 4

Hereinafter, a charged particle beam device 1 according to an embodiment 4 of the present invention will be described with reference to the drawings.

In embodiments 1 to 3, the charged particle beam device 1 includes one ion pump 104. The charged particle beam device 1 according to the present embodiment includes a plurality of ion pumps 104. Hereinafter, as an example, a configuration in which the charged particle beam device 1 includes two ion pumps 104 (that is, the first ion pump and the second ion pump) is described.

In the charged particle beam device 1 such as a semiconductor inspection apparatus, in many cases, the vibration characteristic of the first ion pump and the vibration characteristic of the second ion pump are same or similar to each other. In order to attenuate the natural vibration of the first ion pump and the natural vibration of the second ion pump, the lens barrel 101 and the first ion pump can be connected by the support member 117 described in any one of embodiments 1 to 3, and further, the lens barrel 101 and the second ion pump can be connected by the support member 117 described in any one of embodiments 1 to 3.

Hereinafter, another configuration for attenuating the natural vibration of the first ion pump and the second ion pump will be described.

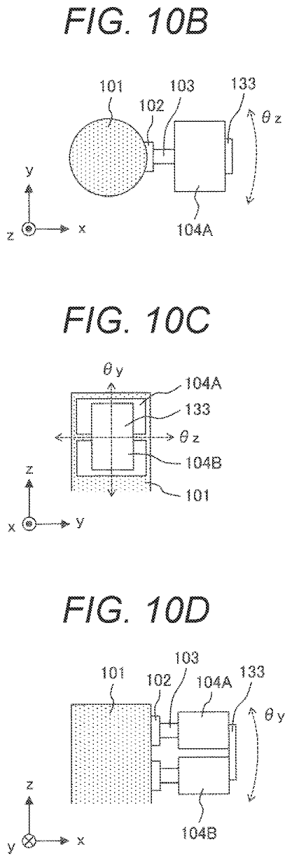

FIG. 10A is a view for explaining natural vibration of ion pumps in a configuration of a charged particle beam device where the first ion pump 104A and the second ion pump 104B are arranged side by side in the z direction and are connected to a lens barrel 101, and these two ion pumps are connected to each other by a connecting member 133. It is assumed that the first ion pump 104A and the second ion pump 104B have the same or similar vibration characteristics.

Experiments and analysis revealed that the charged particle beam device 1 cannot obtain a sufficient damping effect in a case where the first ion pump 104A and the second ion pump 104B are merely connected to each other by the connecting member 133, and the natural vibrations of the ion pumps 104A and 104B are excited mainly in the θy direction and the θz direction.

FIG. 10B, FIG. 10C, and FIG. 10D are a top plan view, a right side view, and a front view, respectively, of the lens barrel 101, a flange 102, a pipe 103, the first ion pump 104A, the second ion pump 104B and the connecting member 133 illustrated in FIG. 10A when a zx plane is set as a front surface. As illustrated in FIG. 10B, among the natural vibrations of the ion pumps 104A, 104B, the modes excited in the θz direction has a component parallel to the xy plane (surface of a sheet on which the drawing is drawn). As illustrated in FIG. 10C, the modes excited in the θy direction and the θz direction each have a component parallel to the yz plane (surface of a sheet on which the drawing is drawn). As illustrated in FIG. 10D, the mode exited in the θy direction has a component parallel to the zx plane (surface of the sheet on which the drawing is drawn).

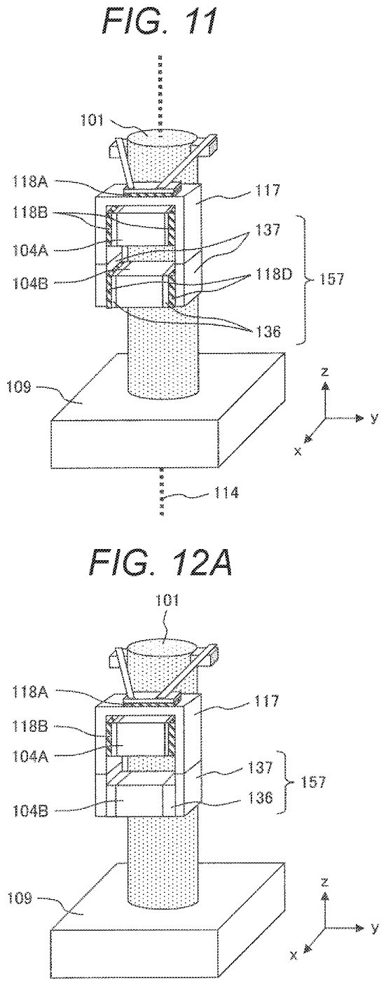

FIG. 11 is a perspective view illustrating a lens barrel 101, a first ion pump 104A, and a second ion pump 104B of the charged particle beam device 1 according to the present embodiment. The charged particle beam device 1 according to the present embodiment differs from the charged particle beam device 1 according to embodiment 3 illustrated in FIG. 9 with respect to a point that the charged particle beam device 1 includes two ion pumps (first ion pump 104A and second ion pump 104B), and the first ion pump 104A and the second ion pump 104B are connected to each other by a support member 117 and a second support member 157. Hereinafter, the points that make the charged particle beam device 1 according to the present embodiment differ from the charged particle beam device 1 illustrated in FIG. 9 are mainly described.

In the charged particle beam device 1 according to the present embodiment, the lens barrel 101 and the first ion pump 104A are connected to each other by the support member 117 (FIG. 9), and the support member 117 and the second ion pump 104B are connected to each other by the second support member 157. That is, the first ion pump 104A and the second ion pump 104B are connected to each other by the support member 117 and the second support member 157.

The second support member 157 includes a second ion pump-side support body 136, a viscoelastic body 118D and a support body 137. One end the second support member 157 is connected to the second ion pump 104B, and the other end of the second support member 157 is connected to the support member 117. The second support member 157 is provided as a member that attenuates the vibration of the first ion pump 104A and the second ion pump 104B.

The second ion pump-side support bodies 136 are connected to the second ion pump 104B. The viscoelastic body 118D is disposed substantially parallel to the zx plane (that is, substantially parallel to a lens barrel central axis 114), and is disposed between a second ion pump-side support body 136 and the support body 137. The support body 137 is connected to the support member 117. In FIG. 11, the viscoelastic body 118D and the support body 137 are disposed on each of two side surfaces (zx planes) of the second ion pump 104B.

In the charged particle beam device 1 according to the present embodiment, one end of the first ion pump 104A is connected to the lens barrel 101, and the other end of the first ion pump 104A is connected to the lens barrel 101 by way of the support member 117 including the viscoelastic bodies 118A and 118B. One end of the second ion pump 104B is connected to the lens barrel 101 and the other end of the second ion pump 104B is connected to the lens barrel 101 by way of the second support member 157 including the viscoelastic body 118D and the support member 117. With such a configuration, the present embodiment provides the charged particle beam device 1 capable of attenuating natural vibration of the first ion pump 104A and the second ion pump 104B that are connected to the lens barrel 101 regardless of a length of the lens barrel 101.

As described with reference to FIG. 10B to FIG. 10D, among the natural vibrations of the ion pumps 104A and 104B, the mode excited in the θy direction has at least a component parallel to the zx plane, and the mode excited in the θz direction has at least a component parallel to the xy plane. In the present embodiment, as illustrated in FIG. 11, the viscoelastic body 118A is arranged substantially parallel to the xy plane. Accordingly, the viscoelastic body 118A can attenuate the natural vibration of the ion pumps 104A, 104B excited in the θz direction. In the present embodiment, the viscoelastic bodies 118B, 118D are arranged substantially parallel to the zx plane. Accordingly, the viscoelastic body 118B, 118D can attenuate the natural vibration of the ion pumps 104A, 104B excited in the θy direction.

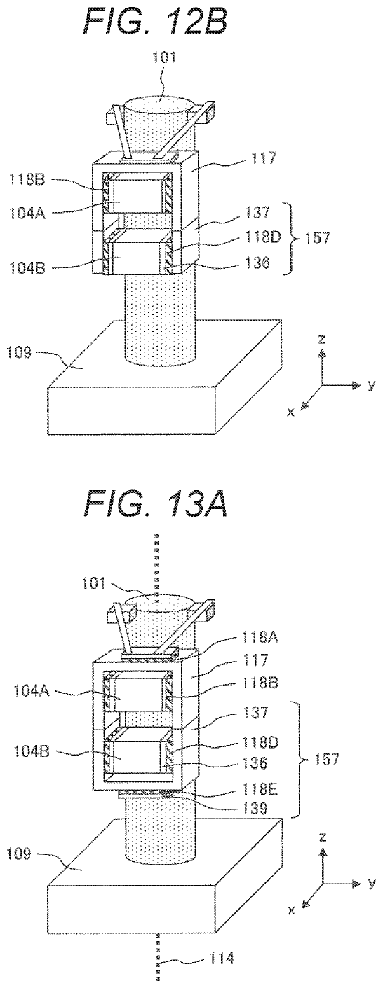

As long as the charged particle beam device 1 according to the present embodiment can attenuate the natural vibration of the ion pumps 104A and 104B to such an extent that the observation of the sample 108 is not affected, the charged particle beam device 1 may not include some of the viscoelastic bodies 118A, 118B, and 118D. FIGS. 12A and 12B illustrate examples of the charged particle beam device 1 having such a configuration.

FIG. 12A is a view illustrating a configuration of the charged particle beam device 1 illustrated in FIG. 11 in which the viscoelastic body 118D is not provided.

FIG. 12B is a view illustrating a configuration of the charged particle beam device 1 illustrated in FIG. 11 in which the viscoelastic body 118A is not provided.

In the charged particle beam device 1 according to the present embodiment, the second support member 157 can also be directly connected to the lens barrel 101 in order to largely attenuate the natural vibration excited particularly in the θz direction with respect to both the first ion pump 104A and the second ion pump 104B. That is, the second support member 157 may be directly connected to the lens barrel 101 without the support member 117 interposed therebetween.

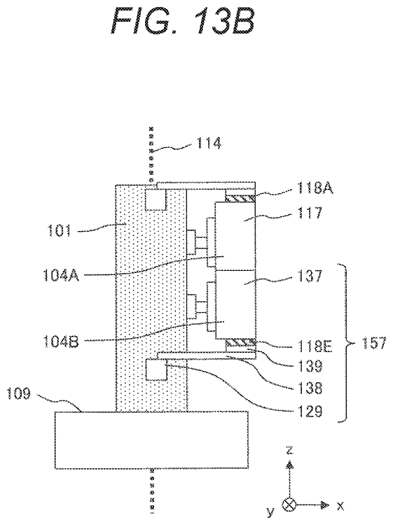

FIG. 13A and FIG. 13B are schematic views illustrating a configuration of the charged particle beam device 1 according to the present embodiment in which the second support member 157 is directly connected to the lens barrel 101. FIG. 13A is a perspective view illustrating the support member 117, the second support member 157, and the lens barrel 101. FIG. 13B is a cross-sectional view illustrating the support member 117, the second support member 157, and the lens barrel 101.

As illustrated in FIG. 13A and FIG. 13B, the support member 117 connects the lens barrel 101 and the first ion pump 104A to each other, and the second support member 157 connects the lens barrel 101 and the second ion pump 104B to each other. The support member 117 and the second support member 157 are connected to each other.

The second support member 157 includes a second ion pump-side support body 136, a viscoelastic body 118D arranged substantially parallel to the zx plane, a support body 137, a viscoelastic body 118E, a stay support portion 139, a stay 138, and a lens barrel connecting portion 129.

The viscoelastic body 118E is disposed substantially parallel to an xy plane (that is, substantially orthogonal to a lens barrel central axis 114), and is disposed between the support body 137 and the stay support portion 139.

The stay support portion 139 is a member where the viscoelastic body 118E is sandwiched between the stay support portion 139 and the support body 137, and the stay support portion 139 supports the stay 138. The stay 138 is a strut member that connects the stay support portion 139 and the lens barrel connecting portion 129 to each other, and connects the second support member 157 to a plurality of portions of the lens barrel 101. The lens barrel connecting portion 129 is provided at a plurality of portions in the circumferential direction of the lens barrel 101, and is a member to which the stay 138 is connected. That is, the second support member 157 is connected to the lens barrel 101 by the stay 138.

The shapes of the viscoelastic bodies 118A, 118B, 118D, 118E are arbitrary, and can be, for example, a sheet shape or a coin shape.

The viscoelastic body 118A and the viscoelastic body 118E may not necessarily be disposed so as to be orthogonal to the lens barrel central axis 114, and the viscoelastic bodies 118B and the viscoelastic bodies 118D may not necessarily be disposed in parallel to the lens barrel central axis 114. For example, provided that the angle between the sheet surface of the viscoelastic body 118A and the lens barrel central axis 114 (that is, the angle of the viscoelastic body 118A with respect to the z direction), the angle between the sheet surface of the viscoelastic body 118E (the surface that is brought into contact with the support body 137 or the stay support portion 139) and the lens barrel central axis 114 (that is, the angle of the viscoelastic body 118E with respect to the z direction), the angle between the sheet surface of the viscoelastic body 118B and the lens barrel central axis 114 (that is, the angle of the viscoelastic body 118B with respect to the z direction), and the angle between the sheet surface of the viscoelastic body 118D (the surface that is brought into contact with the second ion pump-side support body 136 or the support body 137) and the lens barrel central axis 114 (that is, the angle of the viscoelastic body 118 D with respect to the z direction) are each 30 degrees or less, it is possible to sufficiently attenuate the natural vibration of the ion pump 104.

Further, the sheet surface of the viscoelastic body 118A and the sheet surface of the viscoelastic body 118E are not necessarily parallel to the xy plane, and the sheet surface of the viscoelastic body 118B and the sheet surface of the viscoelastic body 118D are not necessarily parallel to the zx plane. For example, provided that the angle between the sheet surface of the viscoelastic body 118A and the xy plane, the angle between the sheet surface of the viscoelastic body 118E and the xy plane, the angle between the sheet surface of the viscoelastic body 118B and the zx plane, and the angle between the sheet surface of the viscoelastic body 118D and the zx plane are each 30 degrees or less, the natural vibrations of the ion pumps 104A and 104B can be sufficiently attenuated.

To enable easy removal of the viscoelastic bodies 118A, 118B, 118D 118E from the ion pumps 104A and 104B, the viscoelastic bodies 118A, 118B, 118D, 118E can be partially or entirely replaced with a laminated structural body 121 illustrated in FIG. 4, for example.

To suppress a change in a magnetic field accompanying the vibration of the second support member 157 itself, it is desirable that the second support member 157 be partially or entirely made of a non-magnetic material in the same manner as the support member 117.

In the present embodiment, the charged particle beam device 1 that includes two ion pumps 104A and 104B has been described. Even in the charged particle beam device 1 that includes three or more ion pumps 104, it is possible to attenuate the natural vibration of three or more ion pumps 104 by using the configuration described in the present embodiment or combining the configuration described in the present embodiment with any of the configurations described in embodiments 1 to 3.

The present invention is not limited to the above-described embodiments, and includes various modifications of these embodiments. For example, the above-described embodiments have been described in detail for facilitating the understanding of the present invention. However, the present invention is not necessarily limited to the modes that includes all constituent elements described above.

Further, a part of the configuration of one embodiment can be replaced with the configuration of another embodiment. Further, a part of the configuration of one embodiment can be added to the configuration of another embodiment. In addition, a part of the configuration of each embodiment can be deleted, or another configuration can be added or replaced.

### REFERENCE SIGNS LIST

1 charged particle beam device

100 conventional charged particle beam device

101 lens barrel

102 flange

103 pipe

104 ion pump

104A first ion pump

104B second ion pump

105 electron gun

106 electron beam

107 electronic lens

108 sample

109 sample chamber

110 stage

111 turbo molecular pump

112 dry pump

113 anti-vibration mount

114 lens barrel central axis

115 mounting surface

117 support member

118, 118A, 118B, 118C, 118D, 118E viscoelastic body

119 ion pump side support body

120 lens barrel side support body

121 laminated structural body

122 first support body

123 viscoelastic body

124 second support body

125 fixing member

128A first lens barrel side support body

128B second lens barrel side support body

129 lens barrel connecting portion

130 stay

131 stay support portion

133 connecting member

136 second ion pump-side support body

137 support body

138 stay

139 stay support portion

157 second support member

1. A charged particle beam device comprising:
a lens barrel that irradiates a charged particle beam to a sample;
an ion pump that is connected to the lens barrel, and evacuates an inside of the lens barrel by discharging a gas; and
a support member having one end connected to the ion pump and the other end connected to the lens barrel, wherein
the support member includes a viscoelastic body that is disposed substantially parallel to a central axis of the lens barrel.

2. The charged particle beam device according to claim 1, wherein
the support member further includes a viscoelastic body disposed so as to be substantially orthogonal to a central axis of the lens barrel.

3. The charged particle beam device according to claim 1, wherein
the charged particle beam device includes a plurality of the ion pumps,
the one end of the support member is connected to one of the plurality of ion pumps.

4. The charged particle beam device according to claim 3, wherein
the support member further includes a viscoelastic body disposed so as to be substantially orthogonal to a central axis of the lens barrel.

5. The charged particle beam device according to claim 3, further comprising a second support member, wherein
referring the ion pump to which the one end of the support member is connected as a first ion pump,
the second support member is connected to one of the ion pumps other than the first ion pump and the support member, and includes a viscoelastic body disposed substantially parallel to a central axis of the lens barrel.

6. The charged particle beam device according to claim 5, wherein
the support member further includes a viscoelastic body disposed so as to be substantially orthogonal to the central axis of the lens barrel.

7. The charged particle beam device according to claim 5, wherein
the second support member is connected to the lens barrel.

8. The charged particle beam device according to claim 7, wherein
the support member further includes a viscoelastic body disposed so as to be substantially orthogonal to a central axis of the lens barrel.

9. The charged particle beam device according to claim 7, wherein
the second support member further includes a viscoelastic body disposed so as to be substantially orthogonal to a central axis of the lens barrel.

10. The charged particle beam device according to claim 1, wherein
the viscoelastic body has a sheet shape.

11. The charged particle beam device according to claim 1, wherein
the support member includes a plurality of holding members at the other end, and is connected to a plurality of portions of the lens barrel by the holding members.

12. The charged particle beam device according to claim 1, wherein
the support member is partially or entirely made of a non-magnetic material.

13. The charged particle beam device according to claim 5, wherein
the second support member is partially or entirely made of a non-magnetic material.
